(19) United States
(12) Patent Application Publication
(10) Pub. No.: US 2009/0141581 A1
(43) Pub. Date: Jun. 4, 2009

(54) Semiconductor Memory Arrangement and System

(76) Inventor: Srdjan Djordjevic, Muenchen (DE)

Correspondence Address: SLATER & MATSIL, L.L.P., 17950 PRESTON ROAD, SUITE 1000, DALLAS, TX, 75252, US

(21) Appl. No.: 11/948,704

(22) Filed: Nov. 30, 2007

(51) Int. Cl. G11C 8/00

(52) U.S. Cl. 365/230.08

(57) ABSTRACT

A semiconductor memory arrangement includes a control device with a first port and a second port, the first and second port being adapted to receive command and address signals, a first buffer device being coupled to the first port, a second buffer device being coupled to the second port and a plurality of memory units at least including a first group of memory units and a second group of memory units.

### TECHNICAL FIELD

Embodiments of the invention relate to semiconductor memory arrangements and semiconductor memory systems.

### BACKGROUND

Memory modules are provided for increasing the memory capacity of a computer system. Originally single inline memory modules (SIMM) were used in personal computers to increase the memory size. A single inline memory module comprises DRAM chips on its printed circuit board (PCB) only on one side. The contacts for connecting the printed circuit board of the single inline memory module (SIMM) are redundant on both sides of the module. A first variant of SIMMs has thirty pins and provides 8 bits of data (9 bits in parity versions). A second variant of SIMMs which are called PS/2 comprise 72 pins and provide 32 bits of data (36 bits in parity versions).

Dual Inline Memory Modules (DIMM) have replaced single inline memory modules (SIMM) as the predominant type of memory modules. While single inline memory modules (SIMMS) have memory units or DRAM chips mounted only on one side of their printed circuit boards (PCB) a dual inline memory modules (DIMMS) comprise memory units mounted on both sides of the printed circuit board of the modules.

There are different types of Dual Inline Memory Modules (DIMM). An unbuffered Dual Inline Memory Module does not contain buffers or registers located on the module. A buffered DIMM, on the other hand, can include buffer or a register on the module.

### BRIEF DESCRIPTION OF THE DRAWINGS

In the accompanying drawings:

FIG. 1 schematically shows a plan view of respective first main surfaces of an embodiment of a semiconductor memory arrangement in a top view;

FIG. 2 schematically shows an embodiment of buffer circuits on a substrate in a top view;

FIG. 3 schematically shows an embodiment of a control device in a top view;

FIG. 4 schematically shows a plan view of respective first main surfaces of an embodiment of a semiconductor memory arrangement in a top view;

FIG. 5 shows a circuit board in a side view of an embodiment of a semiconductor memory arrangement;

FIG. 6 schematically shows a plan view of respective first main surfaces of an embodiment of a semiconductor memory arrangement in a top view;

FIG. 7 schematically shows a plan view of respective second main surfaces of an embodiment of a semiconductor memory arrangement in a top view;

FIG. 8 schematically shows a plan view of respective first main surfaces of an embodiment of a semiconductor memory arrangement in a top view;

FIG. 9 schematically shows a plan view of respective second main surfaces of an embodiment of a semiconductor memory arrangement in a top view; and

FIG. 10 shows a circuit board in a side view of an embodiment of a semiconductor memory arrangement.

### DETAILED DESCRIPTION OF ILLUSTRATIVE EMBODIMENTS

In the following description further aspects and embodiments of the present invention are summarized. In addition, reference is made to the accompanying drawings, which form a part hereof, and in which is shown by way of illustration, in which the invention may be practiced. The embodiments of the drawings present a summary in order to provide a better understanding of one or more aspects of the present invention. This summary is not an extensive overview of the invention and neither intended to limit the features or key-elements of the invention to a specific embodiment. Rather, the different elements, aspects and features disclosed in the embodiments can be combined in different ways by a person skilled in the art to achieve one or more advantages of the present invention. It is to be understood that other embodiments may be utilized and structural or logical changes may be made without departing from the scope of the present invention. The elements of the drawing are not necessarily to scale relative to each other. Like reference numerals designate corresponding similar parts.

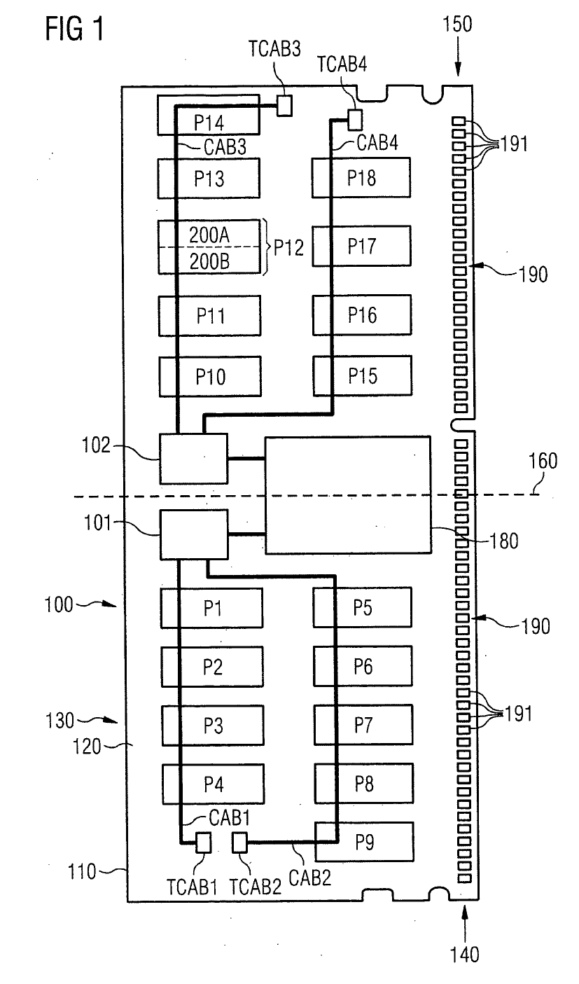

FIG. 1 shows semiconductor memory arrangement 100. The semiconductor memory arrangement 100 can be included in a semiconductor memory system with a controller unit MC, for example, a memory controller (not shown in FIG. 1). At least one semiconductor memory arrangement 100 can be coupled to the controller unit MC via a bus system for transmission of signals. The semiconductor memory system can include one or more semiconductor memory arrangements 100 coupled to the controller unit MC via the bus system. The semiconductor memory arrangement 100 can be a semiconductor memory module, for example, a Fully Buffered Dual In-Line Memory Module (FB-DIMM).

As shown in FIG. 1, the semiconductor memory arrangement 100 comprises a substrate 110 having a first main surface 120, a second main surface 130, a first end 140 and a second end 150. The first and the second main surfaces of the substrate may correspond to a top side and a bottom side, respectively, of the substrate 110. According to FIG. 1, first main surface 120 corresponds to the top surface while the second main surface 130 corresponds to the bottom surface, not visible in FIG. 1.

The first end 140 and the second end 150 are arranged opposite to each other on respective ends of substrate 110. It should be noted that the first end 140 and the second end 150 can be arranged on respective sides relative to an axis 160, which is according to FIG. 1 arranged in the center of substrate 110. Other arrangements, which split substrate 110 into differently sized parts, are conceivably as well.

As shown in FIG. 1, memory units P1, . . . , P18 and a control device 180 are disposed on the first main surface 120 of the substrate 110. In further embodiments, further memory units can be disposed on the second main surface of the substrate as well, as described below.

A connector element 190 including a plurality of contacts 191 is disposed at another end of the substrate 110. In an embodiment, the connector element 190 is an edge connector. The contacts 191 are coupled to inputs of the control device 180 via conductive lines disposed in the substrate 110 (not shown in FIG. 1). In another embodiment, the conductive lines (not shown) can be disposed on the substrate 110.

The external controller unit MC is adapted to transmit signals, for example, control signals, command and address signals, clock signals and data signals to the control device 180 via a bus system coupled to the contacts 191 of the connector element 190 of the substrate 110. Furthermore, the controller unit is adapted to receive signals from the control device 180 via the bus system.

The control device 180 is adapted to receive and to transmit signals via the bus system. Furthermore, the control device 180 is adapted to transmit signals, for example, control signals, command and address signals, clock signals to a first buffer device 101 and a second buffer device 102 arranged symmetrically around axis 160.

The first buffer device 101 and the second buffer device 102 are disposed on the first main surface 120 of the substrate 110.

Furthermore, the control device 180 and the memory units P1, . . . , P18 are disposed on the first main surface 120 of the substrate 110. Each of the memory units of the plurality of memory units includes a first memory chip 200A and a second memory chip 200B. In an embodiment, the respective first memory chips 200A of each of the memory units are disposed on the first main surface 120 of the substrate 110.

Each of the memory units may also comprise one memory chip or more than two memory chips. The first and second memory chips of each of the memory units may be dynamic random access (DRAM) memory chips. The first and second memory chips of each of the memory units may also be synchronous dynamic random access (SDRAM) memory chips.

The control device 180 is adapted to receive signals, for example, control signals, command and address signals and clock signals from a controller such as the memory controller MC as discussed above, to buffer the received control signals, command and address signals and clock signals, to redrive the buffered control signals, command and address signals and clock signals and to transmit the control signals, command and address signals and clock signals to the second first buffer device 101 and to the second buffer device 102. The control device 180 can be an advanced memory buffer chip and the first buffer device and the second buffer device can be register chips.

The first buffer device 101 can be adapted to transmit a first half of the received control signals, command and address signals and clock signals to the memory units.

The second buffer device 102 can be adapted to transmit a second half of the received control signals, command and address signals and clock signals to the memory units.

As shown in FIG. 1, memory units P1, . . . , P18 can be subdivided into a first group of memory units P1, . . . , P9 and a second group of memory units P10, . . . , P18.

Memory units P1, . . . , P4 of a subset of the first group of memory units are disposed on the first main surface 120 of the substrate 110 between the first buffer device 101 and the first end 140 of the substrate 110. Memory units P5, . . . , P9 of a subset of a first group of memory units are disposed between the first buffer device 101 and the first end 140 of the substrate 110 on the first main surface 120 of the substrate 110.

Memory units P10, . . . , P13 of a subset of a second group of memory units are disposed on the first main surface 120 of the substrate 110 between the second buffer device 102 and the second end 150 of the substrate 110. Memory units P14, . . . , P18 of a subset of the second group of memory units are disposed on the first main surface 120 of the substrate 110 between the second buffer device 102 and the second end 150 of the substrate 110.

A first bus system CAB1 including a plurality of conductive lines, wherein only one line is shown in FIG. 1, is coupled to the first buffer device 101 and to the memory units P1, . . . , P4 of the first group of memory units to transmit the received control signals CTRL, command and address signals CA and clock signals CLK from the control device 180 to the memory units of the first group of memory units. For example, a first end of the one line of the first bus system CAB1 is coupled to a first output of the first buffer device 101, a second end of the one line of the first bus system is coupled to a resistor TCAB1 and the memory units of the first group of memory units P1, . . . , P4 are coupled to the one line between the first end and the second end of the one line.

A second bus system CAB2 including a plurality of conductive lines, wherein only one line is shown in FIG. 1, is coupled to the first buffer device 101 and to the memory units P5, . . . , P9 of the first group of memory units to transmit the received control signals CTRL, command and address signals CA and clock signals CLK from the control device 180 to the memory units of the first group of memory units. For example, a first end of the one line of the second bus system CAB2 is coupled to a second output of the first buffer device 101, a second end of the one line of the first bus system is coupled to a resistor TCAB2 and the memory units of the first group of memory units P5, . . . , P9 are coupled to the one line between the first end and the second end of the one line.

In order to distribute the received control signals CTRL, command and address signals CA and clock signals CLK from the control device 180 to the memory units of the first group, the first buffer device 101 can be a multiplexing register, with the first and second output so as to form a 2:1 register circuit.

A third bus system CAB3 including a plurality of conductive lines, wherein only one line is shown in FIG. 1, is coupled to the second buffer device 102 and to the memory units P10, . . . , P14 of the second group of memory units to transmit the received control signals CTRL, command and address signals CA and clock signals CLK from the control device 160 to the memory units of the second group of memory units. For example, a first end of the one line of the third bus system CAB3 is coupled to a first output of the second buffer device 102, a second end of the one line of the first bus system is coupled to a resistor TCAB3 and the memory units of the second group of memory units P10, . . . , P14 are coupled to the one line between the first end and the second end of the one line.

A fourth bus system CAB4 including a plurality of conductive lines, wherein only one line is shown in FIG. 1, is coupled to the second buffer device 102 and to the memory units P15, . . . , P18 of the second group of memory units to transmit the received control signals CTRL, command and address signals CA and clock signals CLK from the control device 180 to the memory units of the second group of memory units. For example, a first end of the one line of the fourth bus system CAB4 is coupled to a first output of the second buffer device 102, a second end of the one line of the first bus system is coupled to a resistor TCAB4 and the memory units of the second group of memory units P15, . . . , P18 are coupled to the one line between the first end and the second end of the one line.

In order to distribute the received control signals CTRL, command and address signals CA and clock signals CLK from the control device 180 to the memory units of the first group, the second buffer device 102 can be a multiplexing register, with the first and second output so as to form a 2:1 register circuit.

The first bus system CAB1, the second bus system CAB2, the third bus system CAB3 and the fourth bus system CAB4 may be disposed in respective conductive and structured layers of the substrate (not shown in FIG. 1).

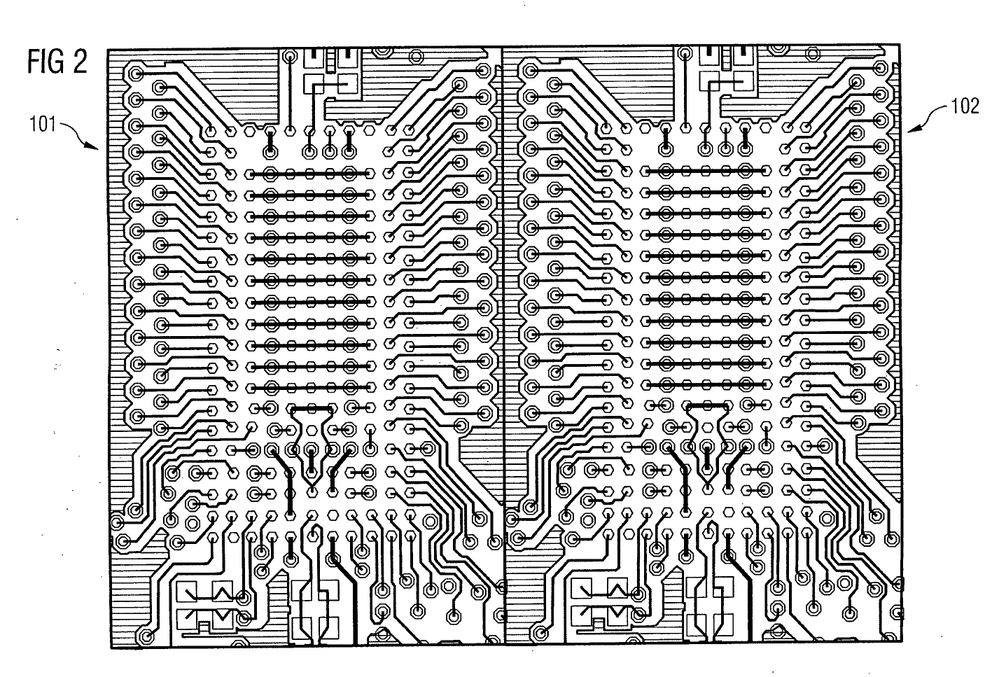

FIG. 2 shows a detailed view of a layout including the first buffer device 101 and the second buffer device 102. As can be seen from FIG. 2, routing space is rather limited. In order to be able to connect respective groups of memory units to the first buffer device 101 and the second buffer device 102, the first buffer device has to be coupled to a first port of the control device 180 and to the first group of memory units so as to transmit said command and address signals. The second buffer device 102 has to be coupled to a second port of the control device 180 and to the second group of memory units so as to transmit the command and address signals.

The first buffer device 101 and the first group of memory units are arranged on the substrate 110 between the axis 160 and the first end 140. The second buffer 102 and the second group of memory units are arranged on the substrate 110 between the axis 160 and the second end 150. Accordingly, the first bus system CAB1 and the second bus system CAB2 being connected to the first buffer device 101 are oriented only towards the first end 140. The third bus system CAB3 and the fourth bus system CAB4 being connected to the second buffer device 102 are oriented only towards the second end 150. Following this, no crossing of lines of the various bus systems occurs and the limited space between the first buffer device 101 and the second buffer device 102 is sufficient to provide the necessary traces.

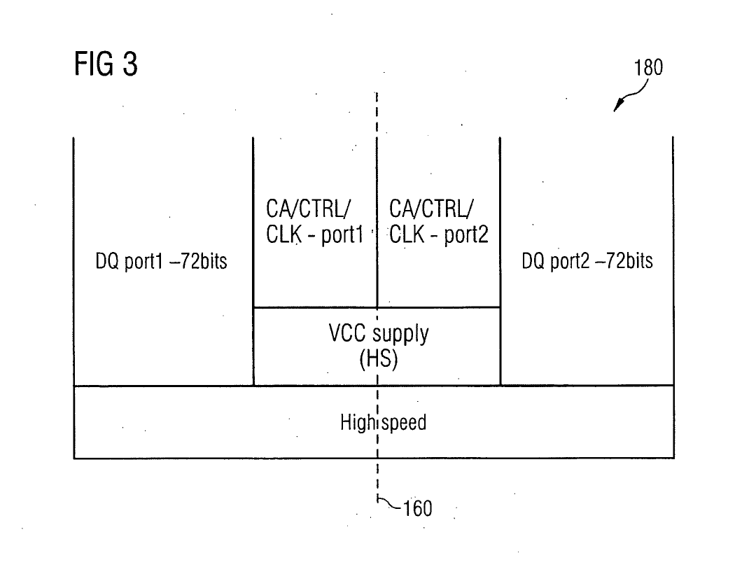

In FIG. 3, a schematic footprint of the control device 180 is shown. The control device 180 includes a first port and a second port, which are adapted to receive command and address signals. The first buffer device is coupled to the first port and the second buffer device is coupled to the second port.

The control device further includes a first data port and a second data port, wherein the first data port is adapted to receive data signals and to transmit a respective data signal to the first group of memory units and the second data port is adapted to receive data signals and to transmit a respective data signal to the second group of memory units.

As can be seen from FIG. 3, the footprint of the control device 180 is also symmetrical with respect to axis 160. This reduces routing space as lines from control device 180 can be directly oriented towards the first buffer device 101 and the second buffer device 102 without crossing.

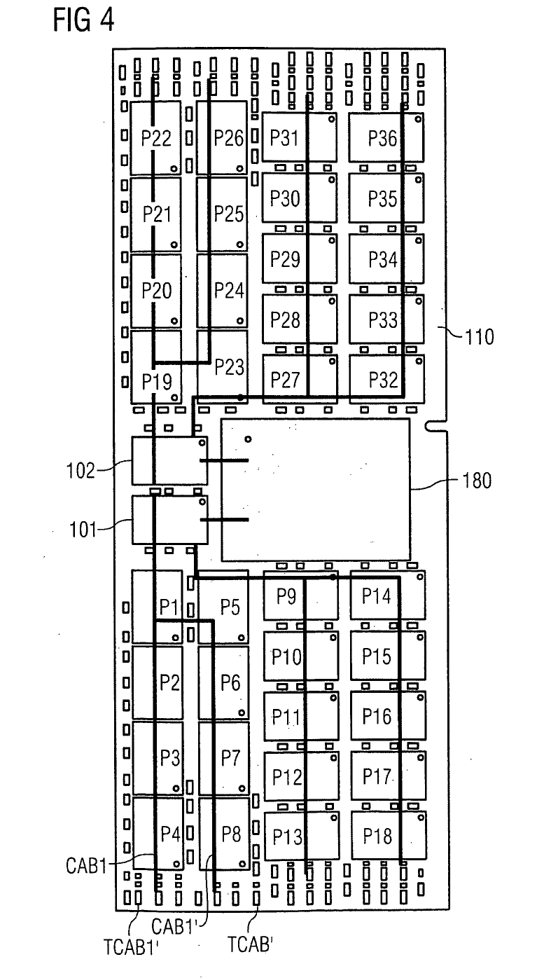

FIG. 4 shows a further embodiment of the semiconductor memory arrangement. As shown in FIG. 4, a plurality of memory units P1, . . . , P36 are disposed on the first main surface 120. The first main surface 120 of the substrate corresponds to a top side of the substrate 110. Each of the memory units of the plurality of memory units comprises a memory chip. Each of the memory units may also comprise two memory chips or more than two memory chips. The one or more memory chips of each of the memory units may be dynamic random access (DRAM) memory chips. The first and second memory chips of each of the memory units may also be synchronous dynamic random access (SDRAM) memory chips.

As shown in FIG. 4, memory units P1, . . . , P36 can be subdivided into a first group of memory units P1, . . . , P18 and a second group of memory units P19, . . . , P36.

Memory units P1, . . . , P8 of a subset of the first group of memory units are disposed on the first main surface 120 of the substrate 110 between the first buffer device 101 and the first end 140 of the substrate 110. Memory units P9, . . . , P18 of a subset of a first group of memory units are disposed between the first buffer device 101 and the first end 140 of the substrate 110 on the first main surface 120 of the substrate 110.

As shown in FIG. 4, the first bus system CAB1 including a plurality of conductive lines is coupled to the first buffer device 101 and to the memory units P1, . . . , P4 of the first group of memory units, as discussed above. In addition, a further first bus system CAB1′ including a plurality of conductive lines is coupled to the first buffer device 101 and to the memory units P5, . . . , P9. For example, a first end of the one line of the first bus system CAB1 is coupled to a first output of the first buffer device 101, a second end of the one line of the first bus system is coupled to the resistor TCAB1 and the memory units of the first group of memory units P1, . . . , P4 are coupled to the one line between the first end and the second end of the one line. A first end of the one line of the first bus system CAB1′ is coupled to the first output of the first buffer device 101, a second end of the one line of the first bus system is coupled to the resistor TCAB1′ and the memory units of the first group of memory units P5, . . . , P9 are coupled to the one line between the first end and the second end of the one line.

The second bus system CAB2, the third bus system CAB3 and the fourth bus system CAB4 can be arranged similar to what has been described with respect to FIG. 4. Furthermore, second bus system CAB2, the third bus system CAB3 and the fourth bus system CAB4 can be arranged similar to FIG. 1 or to any combination of the different embodiments. The first bus system CAB1, second bus system CAB2, the third bus system CAB3 and the fourth bus system CAB4 can be disposed in respective conductive and structured layers of the substrate (not shown in FIG. 4).

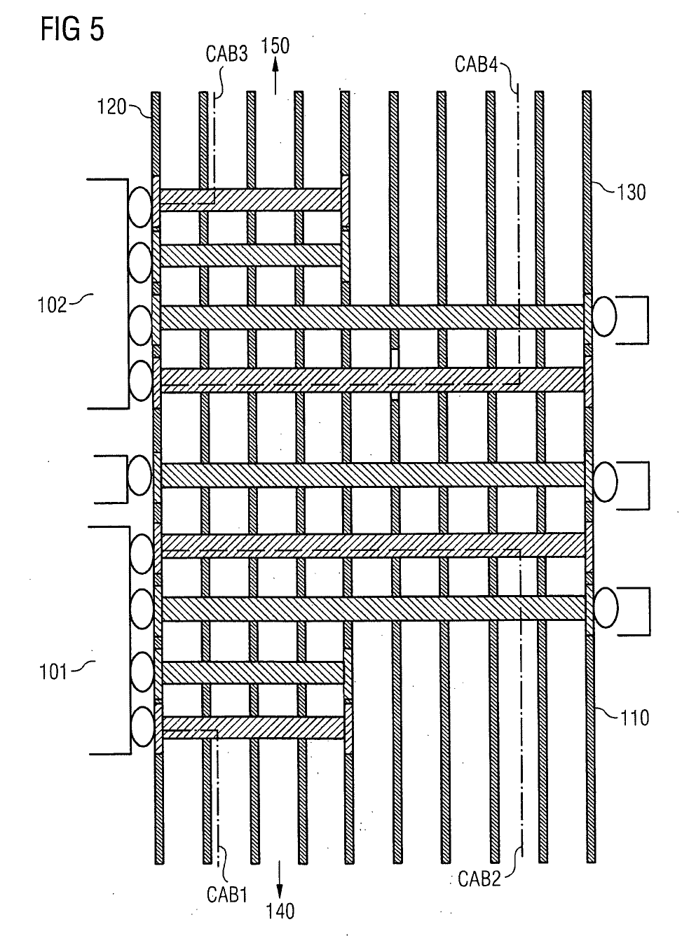

Making reference now to FIG. 5, a circuit board in a side view according to an embodiment of a semiconductor memory arrangement is shown. The first buffer device 101 and the second buffer device 102 are arranged on the first main surface 120. Accordingly, the first bus system CAB1 and the second bus system CAB2 being connected to the first buffer device 101 are oriented only towards the first end 140. The third bus system CAB3 and the fourth bus system CAB4 being connected to the second buffer device 102 are oriented only towards the second end 150. Following this, no crossing of lines of the various bus systems occurs and the limited space between the first buffer device 101 and the second buffer device 102 is sufficient to provide the necessary traces.

The embodiments which were described with respect to FIGS. 1 to 5 are now further enhanced by including semiconductor memory chips on the second main surface 130 of substrate 110. In order to keep the necessary disclosure simple, only differences with respect to FIGS. 1 to 5 are now further described.

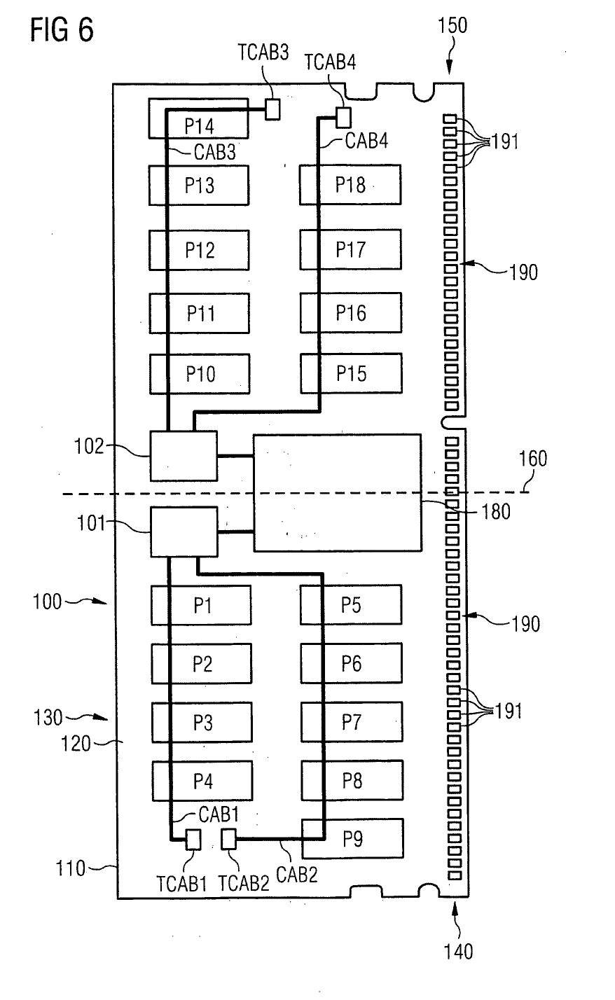

FIG. 6 shows a plan view of a first main surface 120 of an embodiment of a semiconductor memory arrangement.

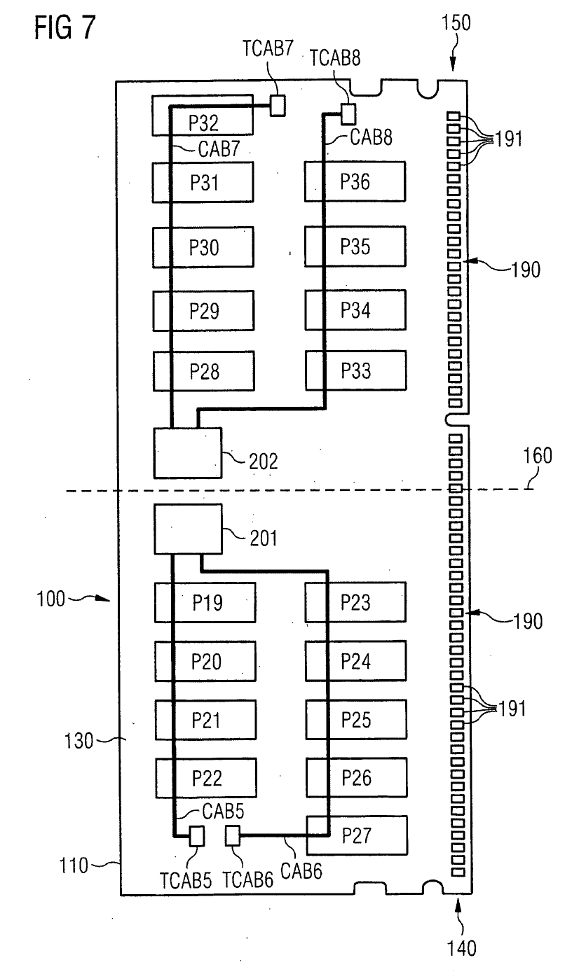

FIG. 7 shows a plan view a plan view of a second main surface 130 of the embodiment of the semiconductor arrangement.

The semiconductor memory arrangement 100 includes a plurality of memory units P1, . . . , P36 are disposed on the first main surface 120 and on the second main surface 130 of the substrate 110. Each of the memory units of the plurality of memory units comprises a first memory chip 200A and a second memory chip 200B. In an embodiment, the respective first memory chips 100A of each of the memory units are disposed on one of the first and the second main surface 120, 130 of the substrate 110 and the respective second memory chips 200B of the corresponding memory unit are disposed on the corresponding first memory chip 200A. Each of the memory units may also comprise one memory chip or more than two memory chips. The first and second memory chips of each of the memory units may be dynamic random access (DRAM) memory chips. The first and second memory chips of each of the memory units may also be synchronous dynamic random access (SDRAM) memory chips.

The substrate 110 may be a circuit board, for example, a printed circuit board, having a plurality of conductive and structured layers disposed between the first main surface 120 and the second main surface 130, wherein respective insulating layers are disposed between adjacent conductive and structured layers (not shown in FIG. 6 or 7).

The control device 180 is disposed on the first main surface 120 of the substrate 110. Furthermore, the memory units P1, . . . , P18 are disposed on the first main surface 120 of the substrate 110. Another second control device 30 and the memory units P19, . . . , P36 are disposed on the second main surface 130 of the substrate 110.

As shown in FIGS. 6 and 7, memory units P1, . . . , P36 can be subdivided into a first group of memory units P1, . . . , P9, a second group of memory units P10, . . . , P18, a third group G3 of memory units P19, . . . , P27, a forth group G4 of memory units P28, . . . , P36.

Memory units P1, . . . , P4 of a subset of the first group of memory units are disposed on the first main surface 120 of the substrate 110 between the first buffer device 101 and the first end 140 of the substrate 110. Memory units P5, . . . , P9 of a subset of a first group of memory units are disposed between the first buffer device 101 and the first end 140 of the substrate 110 on the first main surface 120 of the substrate 110.

Memory units P10, . . . , P13 of a subset of a second group of memory units are disposed on the first main surface 120 of the substrate 110 between the second buffer device 101 and the second end 150 of the substrate 110. Memory units P14, . . . , P18 of a subset of the second group of memory units are disposed on the first main surface 120 of the substrate 110 between the second buffer device 101 and the second end 150 of the substrate 110.

Memory units P19, . . . , P23 of a subset of the third group G3 of memory units are disposed on the second main surface 130 of the substrate 110 between a third buffer device 201 (FIG. 7) and the first end 140 of the substrate 110. Memory units P23, . . . , P27 of a subset of the third group G3 of memory units are disposed between the third buffer device 201 and the first end 140 of the substrate 110 on the second main surface 130 of the substrate 110.

Memory units P28, . . . , P31 of a subset of a fourth group G4 of memory units are disposed on the first main surface 120 of the substrate 110 between the fourth buffer device 202 and the second end 150 of the substrate 110. Memory units P32, . . . , P36 of a subset of the fourth group G4 of memory units are disposed on the first main surface 120 of the substrate 110 between the fourth buffer device 202 and the second end 150 of the substrate 110.

As shown in FIG. 6, first bus system CAB1 including a plurality of conductive lines, wherein only one line is shown in FIG. 1, is coupled to the first buffer device 101 and to the memory units P1, . . . , P4 of the first group of memory units to transmit the received control signals CTRL, command and address signals CA and clock signals CLK from the control device 180 to the memory units of the first group of memory units. For example, a first end of the one line of the first bus system CAB1 is coupled to a first output of the first buffer device 101, a second end of the one line of the first bus system is coupled to a resistor TCAB1 and the memory units of the first group of memory units P1, . . . , P4 are coupled to the one line between the first end and the second end of the one line.

The second bus system CAB2 to eighth bus system CAB8 can be arranged similar to what has been described with respect to FIG. 1. Furthermore, second bus system CAB2 to eighth bus system CAB8 can be arranged similar to FIG. 1 or to any combination of the different embodiments. The first bus system CAB1, CAB8 can be disposed in respective conductive and structured layers of the substrate (not shown in FIG. 4).

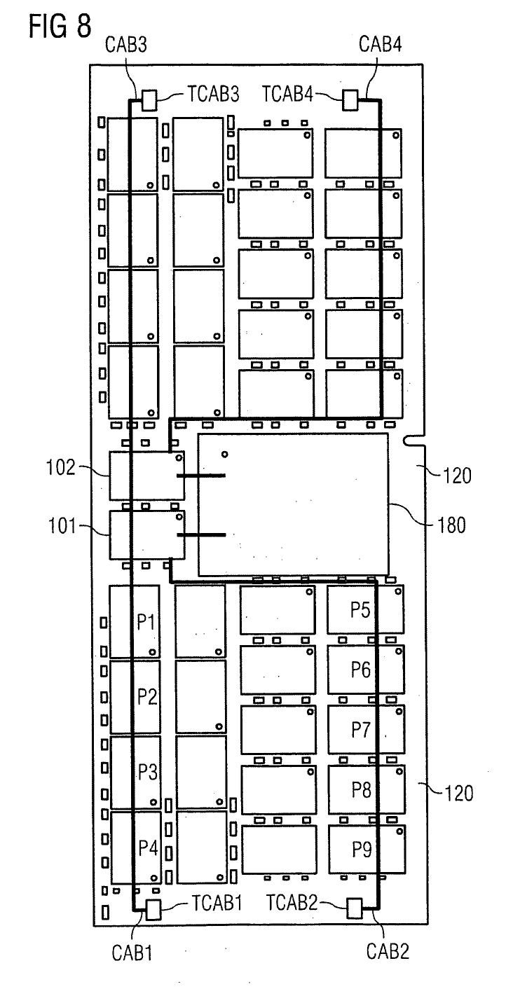

FIG. 8 shows a plan view of a first main surface 120 of an embodiment of a semiconductor memory arrangement.

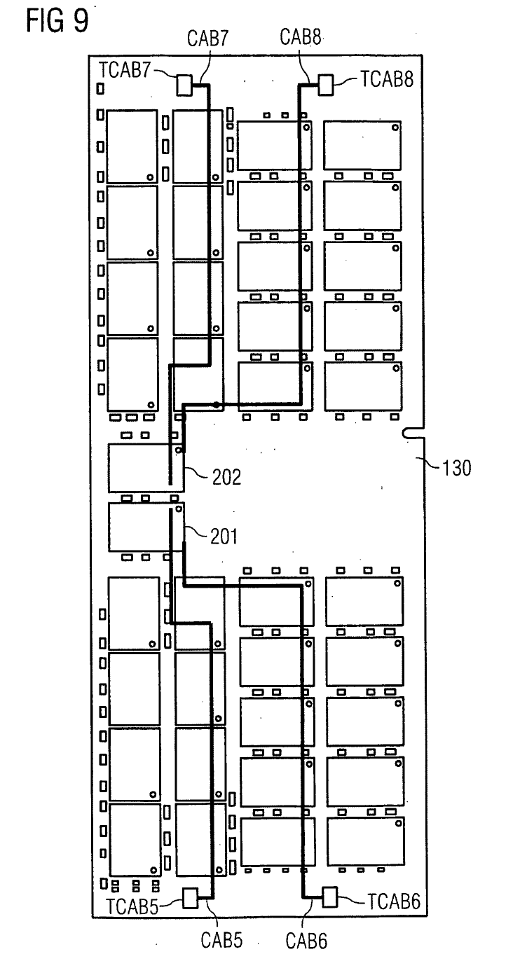

FIG. 9 shows a plan view a plan view of a second main surface 130 of the embodiment of the semiconductor arrangement.

The semiconductor memory arrangement 100 includes a plurality of memory units P1, . . . , P36 are disposed on the first main surface 120 of the substrate 110. As shown in FIG. 8, a plurality of memory units P1, . . . , P36 are disposed on the first main surface 120. The first main surface 120 of the substrate corresponds to a top side of the substrate 110. Each of the memory units of the plurality of memory units comprises a memory chip. Each of the memory units may also comprise two memory chips or more than two memory chips. The one or more memory chips of each of the memory units may be dynamic random access (DRAM) memory chips. The first and second memory chips of each of the memory units may also be synchronous dynamic random access (SDRAM) memory chips.

The semiconductor memory arrangement 100 further includes a plurality of memory units P37, . . . , P72 are disposed on the second main surface 130 of the substrate 110. Each of the memory units of the plurality of memory units comprises a memory chip. Each of the memory units may also comprise two memory chips or more than two memory chips. The one or more memory chips of each of the memory units may be dynamic random access (DRAM) memory chips. The first and second memory chips of each of the memory units may also be synchronous dynamic random access (SDRAM) memory chips.

As shown in FIG. 8, the first bus system CAB1 including a plurality of conductive lines is coupled to the first buffer device 101 and to the memory units P1, . . . , P4 of the first group of memory units, as discussed above. In addition, a further first bus system CAB2 including a plurality of conductive lines is coupled to the first buffer device 101 and to the memory units P5, . . . , P9. For example, a first end of the one line of the first bus system CAB1 is coupled to a first output of the first buffer device 101, a second end of the one line of the first bus system is coupled to the resistor TCAB1 and the memory units of the first group of memory units P1, . . . , P4 are coupled to the one line between the first end and the second end of the one line. A first end of the one line of the first bus system CAB2 is coupled to the first output of the first buffer device 101, a second end of the one line of the first bus system is coupled to the resistor TCAB2 and the memory units of the first group of memory units P5, . . . , P9 are coupled to the one line between the first end and the second end of the one line.

The second bus system CAB2 to eighth bus system CAB8 can be arranged similar to what has been described with respect to FIG. 1. Furthermore, second bus system CAB2 to eighth bus system CAB8 can be arranged similar to FIG. 1 or to any combination of the different embodiments. The first bus system CAB1, CAB8 can be disposed in respective conductive and structured layers of the substrate (not shown in FIG. 4).

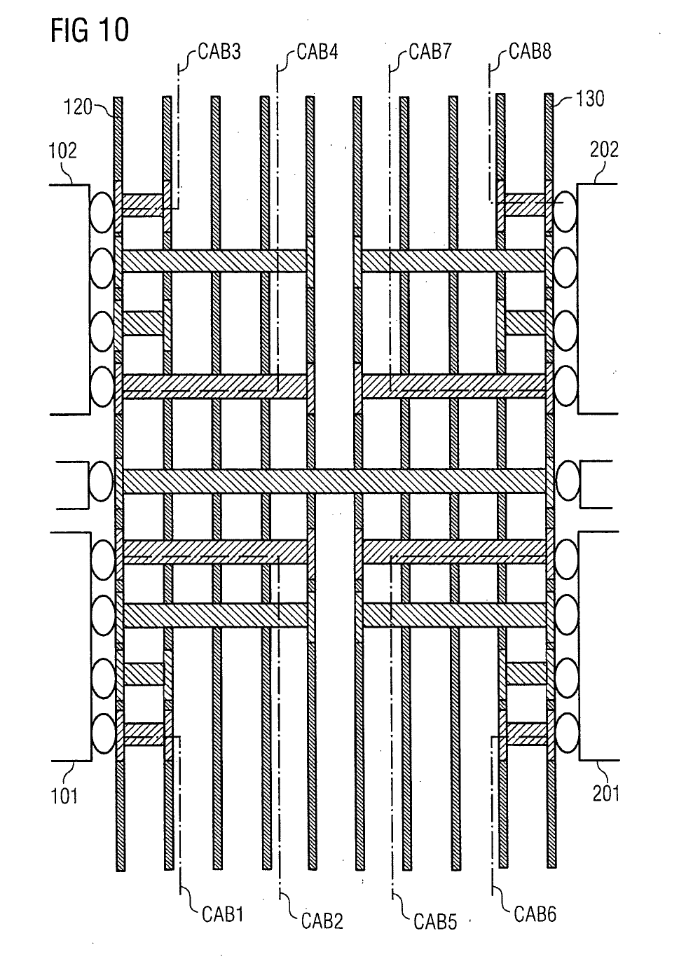

Making reference now to FIG. 10, a circuit board in a side view according to an embodiment of a semiconductor memory arrangement is shown. The first buffer device 101 and the second buffer device 102 are arranged on the first main surface 120. The third buffer device 201 and the fourth buffer device 202 are arranged on the second main surface 130.

Accordingly, the first bus system CAB1 and the second bus system CAB2 being connected to the first buffer device 101 are oriented only towards the first end 140. The third bus system CAB3 and the fourth bus system CAB4 being connected to the second buffer device 102 are oriented only towards the second end 150.

Accordingly, the fifth bus system CAB5 and the sixth bus system CAB6 being connected to the third buffer device 201 are oriented only towards the first end 140. The seventh bus system CAB7 and the eighth bus system CAB8 being connected to the fourth buffer device 202 are oriented only towards the second end 150.

Following this, no crossing of lines of the various bus systems occurs and the limited space between the first buffer device 101 and the second buffer device 102 is sufficient to provide the necessary traces.

Although specific embodiments have been illustrated and described herein, it will be appreciated by those of ordinary skill in the art, that any arrangement which is calculated to achieve the same purpose may be substituted for the specific embodiments shown. It is to be understood, that the above description is intended to be illustrative and not restrictive. This application is intended to cover any adaptations or variations of the invention. Combinations of the above embodiments and many other embodiments will be apparent to those of skill in the art upon reading and understanding the above description. The scope of the invention includes any other embodiments and applications in which the above structures and methods may be used. The scope of the invention should, therefore, be determined with reference to the appended claims along with the scope of equivalents to which such claims are entitled.

What is claimed is:

1. A semiconductor memory arrangement comprising:
a control device with a first port and a second port, the first and second port each being adapted to receive command and address signals;
a first buffer device coupled to the first port;
a second buffer device coupled to the second port;
a plurality of memory units comprising a first group of memory units and a second group of memory units, wherein the first buffer device is adapted to transmit the command and address signals from the first port to the first group of memory units and the second buffer device is adapted to transmit the command and address signals from the second port to the second group of memory units.

2. The semiconductor memory arrangement according to claim 1, wherein the first buffer device comprises a register.

3. The semiconductor memory arrangement according to claim 2, wherein the second buffer device comprises a register.

4. The semiconductor memory arrangement according to claim 1 further comprising a third group of memory units and a fourth group of memory units, wherein the first buffer device is adapted to transmit the command and address signals from the first port to the third group of memory units and the second buffer device being adapted to transmit the command and address signals from the second port to the memory units of the fourth group of memory units.

5. The semiconductor memory arrangement according to claim 1, further comprising a substrate with a first main surface and a second main surface, the control device being disposed on the first main surface.

6. The semiconductor memory arrangement according to claim 5, wherein the first buffer device and the second buffer device are disposed on the first main surface.

7. The semiconductor memory arrangement according to claim 5, wherein the memory units of the plurality of memory units are disposed on the first main surface of the substrate.

8. The semiconductor memory arrangement according to claim 5, wherein a subset of the memory units of the plurality of memory units is disposed on the first main surface of the substrate and a further subset of the memory units of the plurality of memory units is disposed on the second main surface of the substrate.

9. The semiconductor memory arrangement according to claim 1, wherein the control device further comprises a first data port and a second data port, wherein the first data port is adapted to receive data signals and to transmit a respective data signal to the first group of memory units and the second data port is adapted to receive data signals and to transmit a respective data signal to the second group of memory units.

10. The semiconductor memory arrangement according to claim 1 further comprising a connector element disposed on the substrate, wherein the control device is adapted to receive the command and address signals from the connector element.

11. The semiconductor memory arrangement according to claim 10, wherein the control device is adapted to receive the data signals from the connector element.

12. A semiconductor memory arrangement comprising:
a control device with a first port and a second port, the first and second port each being adapted to receive command and address signals;
a first buffer device coupled to the first port;
a second buffer device coupled to the second port;
a third buffer device coupled to the first port;
a fourth buffer device coupled to the second port;
a plurality of memory units comprising a first group of memory units, a second group of memory units, a third group of memory units and a fourth group of memory units;
wherein the first buffer device is adapted to transmit the command and address signals from the first port to a subset of the first and third group of memory units, the second buffer device is adapted to transmit the command and address signals from the second port to a subset of the second and fourth group of memory units, the third buffer device is adapted to transmit the command and address signals from the first port a further subset of the first and third group memory units and the fourth buffer device is adapted to transmit the command and address signals from the second port to a further subset of the second and fourth group of memory units.

13. The semiconductor memory arrangement according to claim 12, further comprising a substrate with a first main surface and a second main surface, the control device, the first buffer device and the second buffer device being disposed on the first main surface.

14. The semiconductor memory arrangement according to claim 13, wherein the third buffer device and the fourth buffer device are disposed on the second main surface.

15. The semiconductor memory arrangement according to claim 14, wherein the subset of the first and third group of memory units and the subset of the second and fourth group of memory units are disposed on the first main surface of the substrate.

16. The semiconductor memory arrangement according to claim 15, wherein the further subset of the first and third group of memory units and the further subset of the second and fourth group of memory units are disposed on the second main surface of the substrate.

17. A semiconductor memory module, comprising:
a circuit board having a first end and a second end, wherein the first end and the second end are arranged opposite relative to an axis;
a control device with a first port and a second port, the first and second port each being adapted to receive command and address signals and being arranged on the circuit board symmetrically relative to the axis;
a plurality of memory units comprising a first group of memory units and a second group of memory units;
a first buffer device being coupled to the first port and to the first group of memory units so as to transmit the command and address signals;
a second buffer device being coupled to the second port and to the second group of memory units so as to transmit the command and address signals;
wherein the first buffer device and the first group of memory units are arranged on the circuit board between the axis and the first end and the second buffer and the second group of memory units are arranged on the circuit board between the axis and the second end.

18. The semiconductor memory module according to claim 17, wherein the circuit board comprises at least two routing layers having electrically conductive tracers, wherein the command and address signals are arranged between the first buffer device and the first group of memory units between the axis and the first end on the at least two routing layers and wherein the command and address signals are arranged between the second buffer device and the second group of memory units between the axis and the second end on the at least two routing layers.

19. The semiconductor memory module according to claim 18, further comprising termination circuits being coupled to the command and address signals between the first buffer device and the first group of memory units and being arranged in proximity to the first end.

20. The semiconductor memory module according to claim 18, further comprising termination circuits being coupled to the command and address signals between the second buffer device and the second group of memory units and being arranged in proximity to the second end.

21. A semiconductor memory system, comprising:
a controller;
at least one semiconductor memory module comprising:
a control device with a first port and a second port, the first and second port being adapted to receive command and address signals;
a first buffer device coupled to the first port;
a second buffer device coupled to the second port;
a plurality of memory units comprising a first group of memory units and a second group of memory units;
wherein the first buffer device is adapted to transmit the command and address signals from the first port to the first group of memory units and the second buffer device is adapted to transmit the command and address signals from the second port to the second group of memory units.

22. The semiconductor memory system according to claim 21, wherein the control device further comprises a first data port and a second data port, wherein the first data port is adapted to receive data signals and to transmit a respective data signal to the first group of memory units and the second data port is adapted to receive data signals and to transmit a respective data signal to the second group of memory units.

23. The semiconductor memory system according to claim 21, further comprising a third group of memory units and a fourth group of memory units, wherein the first buffer device being adapted to transmit the command and address signals from the first port to the third group of memory units and the second buffer device being adapted to transmit the command and address signals from the second port to the memory units of the fourth group of memory units.

24. The semiconductor memory system according to claim 23, wherein the first buffer device and the second buffer device include multiplexing circuits configured to transmit the command and address signals from the first or second port to a respective group of memory units.

25. A semiconductor memory arrangement comprising:
means for receiving command and address signals;
means for storing data;
means for transmitting the command and address signals from the means for receiving to the means for storing data;
wherein the means for transmitting the command and address signals are adapted to transmit the command and address signals to a first group of memory units and a second group of memory units.
